(19) United States
(12) Patent Application Publication
(10) Pub. No.: US 2026/0243803 A1
(43) Pub. Date: Aug. 20, 2026

(54) APPARATUS FOR TESTING AN ELECTRONIC DEVICE

(71) Applicant: JCET STATS ChipPAC Korea Limited, Incheon (KR)

(72) Inventors: MyungKi KIM, Incheon (KR); DongMin KIM, Gyeonggi-do (KR); DongWook KIM, Incheon (KR)

(21) Appl. No.: 19/536,270

(22) Filed: Feb. 11, 2026

(30) Foreign Application Priority Data
Feb. 14, 2025 (CN) 202510166097.1

(51) Int. Cl. G01R 1/073

(52) U.S. Cl. CPC G01R 1/07378; G01R 1/07371

(57) ABSTRACT

An apparatus for testing an electronic device is provided. The apparatus includes: a test board; a test socket disposed on the test board, wherein the test socket includes a socket body, and a plurality of contact pins vertically extending through the socket body; and a probe assembly including a socket jig and a test probe operably mounted on the socket jig, wherein, when the socket jig is mounted on the test socket, the socket jig fixes the test probe relative to the test socket and guides the test probe to contact with a target contact pin of the plurality of contact pins.

### TECHNICAL FIELD

The present application generally relates to semiconductor technology, and more particularly, to an apparatus for testing an electronic device.

### BACKGROUND OF THE INVENTION

The semiconductor industry is constantly faced with complex integration challenges as consumers want their electronics to be smaller, faster and higher performance with more and more functionalities packed into a single device. For example, electronic devices that have undergone complicated processing are subjected to various types of electrical tests for testing their characteristics and for identifying their potential defects.

To this end, a test socket is used to electrically connect metallic wires or contact pads of a test board (for example, a printed circuit board) mounted in test equipment with connectors or terminals of an electronic device to be tested. That is, when an electronic device is tested, the test socket serves as an interface to electrically connect the test board of the test equipment with the electronic device under test. Establishing the connection between the test equipment and the electronic device under test may induce a path loss that results in deterioration of the device performance, especially when the electronic device is tested at a high frequency. Thus, the path loss should be calibrated from test results of the electronic device to remove the deterioration of the device performance that occurs during the testing process, and improve accuracy of the test results. However, it is difficult to measure the path loss induced by the test socket and the test board accurately by using existing test apparatuses.

Therefore, a need exists for an apparatus for testing an electronic device.

### SUMMARY OF THE INVENTION

An objective of the present application is to provide an apparatus for testing an electronic device with improved accuracy or improved reliability.

According to an aspect of the present application, an apparatus for testing an electronic device is provided. The apparatus may include: a test board; a test socket disposed on the test board, wherein the test socket includes a socket body, and a plurality of contact pins vertically extending through the socket body; and a probe assembly including a socket jig and a test probe operably mounted on the socket jig, wherein, when the socket jig is mounted on the test socket, the socket jig fixes the test probe relative to the test socket and guides the test probe to contact with a target contact pin of the plurality of contact pins.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a test probe for testing a contact pin of a test socket.

FIG. 2A illustrates a schematic diagram of an apparatus for testing an electronic device according to an embodiment of the present application.

FIG. 2B is a perspective view of the apparatus of FIG. 2A.

FIG. 2C is an exploded view of the apparatus of FIG. 2A.

FIG. 2D is a cross-sectional and exploded view of the apparatus of FIG. 2A.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, when an electronic device is being tested by a test apparatus including a test socket and a test board, a path loss may be inevitably induced into test results generated by the test apparatus. To be more specific, the test socket may include contact pins (for example, pogo pins) which help establish electrical connections between the electronic device and the test board to test the electronic device. During this testing process, the path losses of the contact pins and other components in signaling paths may inevitably occur and be incorporated within a test result of the electronic device. Therefore, it is desired to calibrate or remove the path loss from the test result, so as to improve accuracy of the test result of the electronic device.

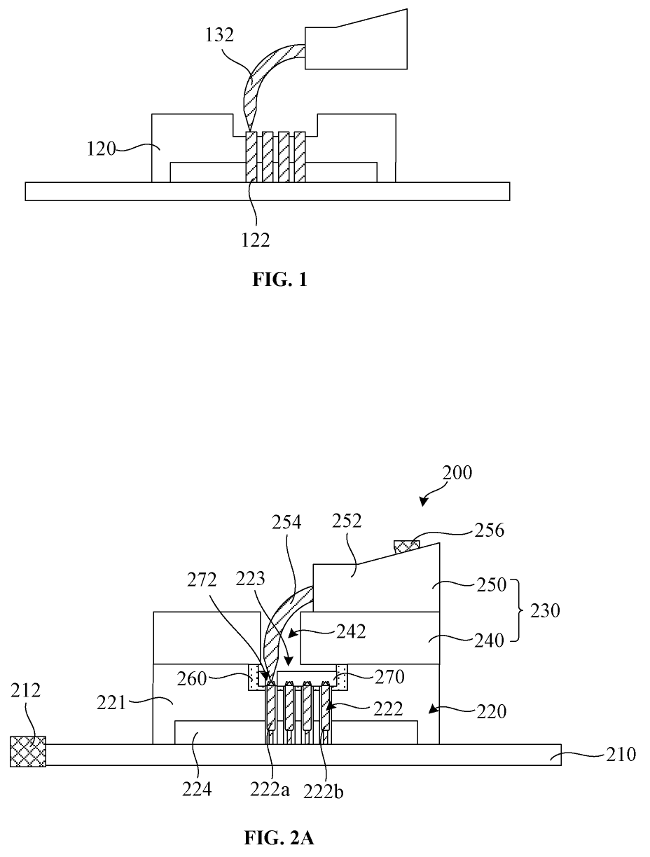

Some solutions have been provided to measure path losses of contact pins. For example, a simulation of the path loss, or a pre-measured result of the path loss provided by contact pin vendors may be used for calibration of a test result of an electronic device under test, instead of an actual measurement of the path loss when the electronic device is being tested. However, since this calibration information which is generated or measured beforehand is obtained in environments different from an actual testing environment of the electronic device, the accuracy of the calibration information of the path loss may still be unsatisfactory. In addition, when the path loss is measured beforehand, probes are generally used for connecting the contact pins to measure the path losses. For example, as shown in FIG. 1, a test probe 132 contacts with a contact pin 122 of a test socket 120 to measure an impedance of the contact pin 122. However, as the contact pin 122 is small and invisible to human eyes, a microscope is required to observe the contact pin 122, and a probe station is required to move the test probe 132 to ensure a reliable connection between the test probe 132 and the contact pin 122. Thus, the process may be complicated and may suffer from several issues such as poor contact reliability and deficient probe durability.

To address at least one of the above issues, an apparatus for testing an electronic device is provided in embodiments of the present application. In the apparatus, a test probe is operably mounted on a socket jig to form a probe assembly. When the socket jig is mounted onto a test socket, the socket jig can fix the test probe relative to the test socket and guide the test probe to contact with a target contact pin within the test socket. As the test socket is further mounted on a test board, a measurement result can be generated by measuring an electrical characteristic associated with a testing path between the test board and the test probe and passing through the target contact pin. For example, the measurement result can be used to determine an impedance of the target contact pin. In the apparatus of the present application, the test probe is mounted on a socket jig and can be guided to contact with the target contact pin by mounting the socket jig onto the test socket, ensuring a reliable connection between the test probe and the target contact pin. Thus, the path loss and the impedance of the target contact pin can be easily measured without the need for a microscope or a probe station.

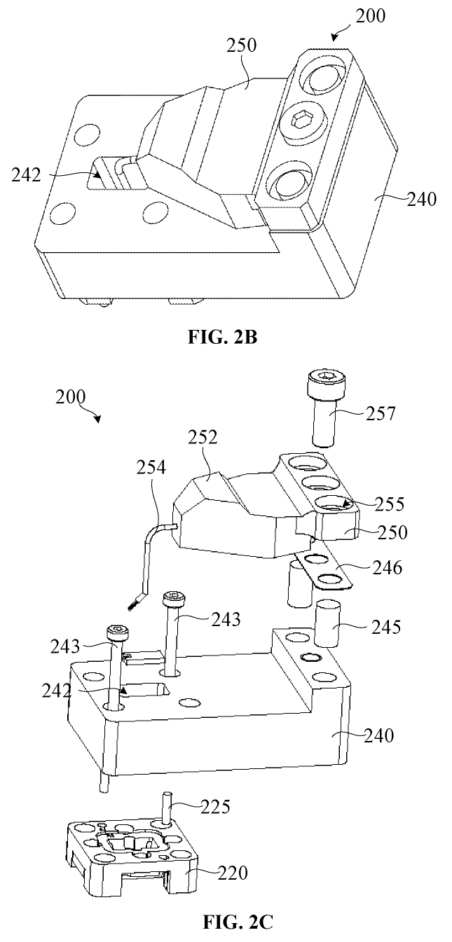

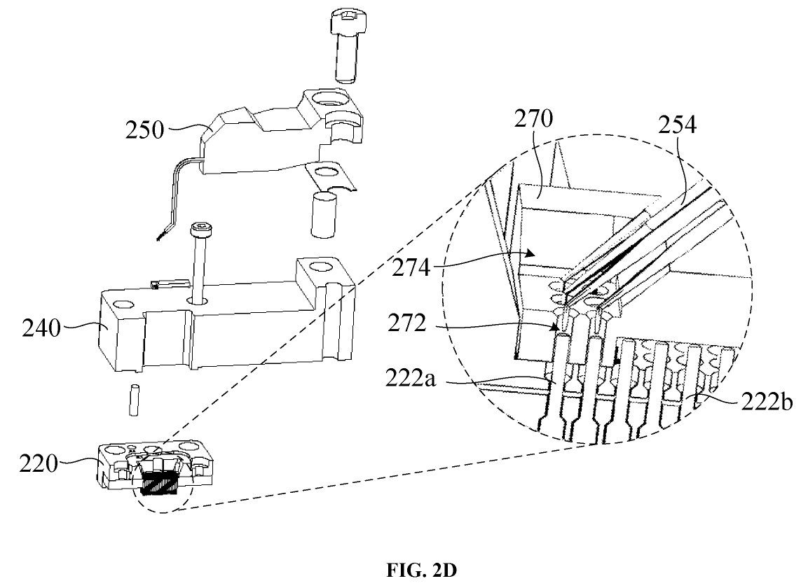

FIGS. 2A to 2D illustrate an apparatus 200 for testing an electronic device according to an embodiment of the present application. In particular, FIG. 2A illustrates a schematic diagram of the apparatus 200, FIG. 2B is a perspective view of the apparatus 200, FIG. 2C illustrates an exploded view of the apparatus 200, and FIG. 2D illustrates a cross-sectional and exploded view of the apparatus 200. The apparatus 200 can operate in a test mode under which a test result of the electronic device can be generated, or in a calibration mode under which calibration information (for example, path loss) for the test result can be generated. In the following, the apparatus 200 operating in the calibration mode will be described in detail with reference to FIGS. 2A to 2D.

As shown in FIGS. 2A to 2D, the apparatus 200 may include a test board 210, a test socket 220 and a probe assembly 230. The test socket 220 is operably mounted on the test board 210, and includes a socket body 221 and a plurality of contact pins 222 vertically extending through the socket body 221. The probe assembly 230 includes a socket jig 240 and a test probe 250 operably mounted on the socket jig 240. When the socket jig 240 is mounted on the test socket 220, the socket jig 240 fixes the test probe 250 relative to the test socket 220 and guides the test probe 250 to contact with a target contact pin 222a of the plurality of contact pins 222.

The test board 210 may serves as a base of the apparatus 200. The test board 210 may be electrically connected with the electronic device in the test mode. Also, the test board 210 may be electrically coupled to test equipment such as a multimeter with or without a signal generator for testing the electronic device.

In some embodiments, the test board 210 includes a device placement region for placing a testing fixture (for example, the test socket 220) and the electronic device under test. Furthermore, the test board 210 includes a test region where a test tool can be placed and/or connected such that the test tool can be electrically coupled with the electronic device to collect a measurement of the electronic device before or during a testing process of the electronic device. In some embodiments, the device placement region may be a central zone of the test board 210, and the test region may be a peripheral zone of the test board 210. Alternatively, the test region may be at a back side of the test board 210 as long as it is convenient for the test tool to get access to. Furthermore, a signaling route such as a metallic wire may be included within the test board 210, which is used for transmitting signals between the electronic device and the test equipment. For example, during the testing of the electronic device, the signaling route may be coupled with the signal generator of the test equipment to receive and apply to the electronic device a test signal. In some embodiments, the signaling route may have a respective layout corresponding to a layout of the electronic device, for example, a specific length corresponding to a size of the electronic device. However, the configuration of the test board 210 and the test equipment is exemplary and not mandatory. In some alternative embodiment, the test board 210 may integrate within itself all the functions such as signal generation and electrical measurement which are desired for the testing of the electronic device, and thus no further test equipment is needed.

In the embodiment shown in FIG. 2A, the test board 210 may be an evaluation board (EVB). The EVB is a hardware platform provided by a manufacturer or supplier of the electronic device to evaluate the performance and functionality of the electronic device. The EVB may include peripheral circuits, interfaces, and components that are compatible with the electronic device. The electronic device to be tested may include various types of electronic modules, for example, a Radio Frequency (RF) device, and the calibration information to be tested may include RF characteristics. A first RF connector 212 such as a sub miniature push-on (SMP) connector may be mounted on the test board 210 and electrically coupled with the signaling route therein. Then, the test equipment may be electrically coupled with the test board 210 via the first RF connector 212. For example, the test equipment may be a vector network analyzer (VNA), which is used in a wide range of RF and high frequency applications. However, the present application is not limited to the above examples, and other connecters and test equipment can be used according to actual needs.

Referring to FIG. 2A, the test socket 220 is operably mounted on the test board 210. In the test mode, the test socket 220 is used for accommodating the electronic device therewithin, and at the same time, providing an electrical connection between the electronic device and the test board 210, so as to build a complete test environment or system to test the electronic device.

In some embodiments, the test socket 220 includes a socket body 221 which may be constructed to have a cuboid structure, and is disposed on the test board 210, or particularly, on the device placement region. The socket body 221 may have a plurality of through holes extending from its upper surface to its lower surface. Moreover, the test socket 220 includes a plurality of contact pins 222 vertically extending through the socket body 221 and accommodated within the plurality of through holes, respectively. The contact pins 222 are movable vertically relative to the socket body 221. During a testing process of the electronic device, the contact pins 222 can establish an elastic and electrical connection between the electronic device and the test board 210. Top portions and bottom portions of the contact pins 222 may be exposed from the upper surface and the lower surface of the socket body 221 respectively to allow for a convenient connection with the electronic device and the test board 210.

As shown in FIG. 2A, the socket body 221 may include a socket base and a side wall surrounding the socket base. In some embodiments, the socket base may be a central portion of the socket body 221, and the side wall may be a peripheral portion of the socket body 221, such that the side wall defines a cavity 223 above the socket base. The cavity 223 exposes the upper surface of the socket base and the top portions of the contact pins 222, and also accommodates the electronic device in the test mode. In some other embodiments, the socket body 221 may be assembled from multiple individual components. For example, the socket body 221 may further include a bottom plate 224 embedded within the socket base as shown in FIG. 2A. In another example, the socket base and the side wall may be provided separately and be assembled together before the testing or calibration process. However, the present application is not limited thereto. In some other embodiments, the socket base and the side wall may be formed as an integral piece.

The contact pins 222 may include at least one target contact pin 222a, each of which is electrically connected with a signaling route of the test board 210. For example, when the apparatus 200 is used to test an RF device or measure RF characteristics associated with the testing path, the target contact pin 222a may be used to receive or output various RF signals. Apart from the target contact pin 222a, the contact pins 222 also include at least one non-target contact pin 222b which may not be electrically coupled with the signaling route of the test board 210. The non-target contact pin 222b may be used for other purposes such as powering, grounding or connection with other signaling routes (e.g., non-target signaling routes). The target contact pin 222a and the non-target contact pin 222b may have the same structure.

In some embodiments, the contact pins 222 may include pogo pins. Each pogo pin includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with the top contactor at its top end, and can be in contact with the bottom contactor at its bottom end. As such, the pogo pins can be movable vertically relative to the socket body 221 with the coil spring providing an elastic connection between the electronic device under test and the test board 210. With these configurations, when the electronic device is being tested by the test socket 220, the top contactors of the pogo pins 222 can be in contact with conductive pads of the electronic device, and the bottom contactors can be in contact with contact pads in the device placement region of the test board 210. Additionally, the top contactors and the bottom contactors are exposed from the upper surface and the back surface of the socket body 221. When the electronic device is being tested by the test socket 220, the contact pins 222 may be pressed against the test board 210 to set up a reliable electrical connection between the electronic device and the test board 210, which builds a complete test environment or system to test the electronic device. It could be appreciated that, in some other embodiments, the contact pins may include other types of elastic connectors, such as elastic conductive pillars.

In some embodiments, the apparatus 200 may further include an inner plate 260. The inner plate 260 may be arranged on the test socket 220 and accommodated within the cavity 223 of the test socket 220. In the example shown in FIG. 2A, the inner plate 260 may include a platform and a sidewall around the platform, which can be used for accommodating the electronic device during the test mode, or for accommodating a guide block 270 during the calibration mode. The contact pins 222 may vertically extend through the inner plate 260, and the inner plate 260 may include a plurality of through holes to receive the contact pins 222, respectively. The top portions of the contact pins 222 may be exposed from the inner plate 260 for connection with the electronic device during the test mode.

Referring to FIG. 2A, the apparatus 200 may further include a guide block 270. The guide block 270 may have a shape mating with the inner plate 260, such that the guide block 270 can be disposed on the inner plate 260 and within the cavity 223 of the test socket 220. The guide block 270 may cover the non-target contact pin 222b, but include a through hole 272 to expose the target contact pin 222a, such that when the socket jig 240 is mounted on the test socket 220, the through hole 272 can further guide the test probe 250 to contact with the target contact pin 222a. The guide block 270 may be made of an insulating material such as polyamide-imide. More detail about the guide block 270 will be described below with reference to FIG. 2D.

As shown in FIGS. 2A to 2C, the probe assembly 230 includes the socket jig 240 and the test probe 250. In some embodiments, the test probe 250 includes a probe base 252 and a probe tip 254 mounted on the probe base 252. The probe base 252 is operably mounted on the socket jig 240, and the socket jig 240 includes a through hole 242 extending from its upper surface to its lower surface. Accordingly, when the socket jig 240 is mounted on the test socket 220, the probe tip 254 can pass through the through hole 242 of the socket jig 240 to contact with the target contact pin 222a. As shown in FIG. 2A, a second RF connector 256 may be mounted on the probe base 252 and electrically connected with the probe tip 254. Thus, the probe tip 254 can be electrically connected with the test equipment (for example, a vector network analyzer (VNA)) via the second RF connector 256. In an example, the second RF connector 256 may be a “Radio Frequency connector, Subminiature, type A” (SMA) connector. The SMA connector has screw type coupling mechanism which minimizes reflections and attenuation by ensuring uniform contact, and can be used in a wide range of applications including antenna connections for most sub 6 GHz technologies like Wi-Fi and Bluetooth. However, the present application is not limited to the above example, and in some other examples, the second RF connector 256 may be other connectors suitable for high-frequency communication.

Referring to FIG. 2C, the test socket 220 includes one or more first guide pins 225 protruding from its upper surface, and accordingly, the socket jig 240 includes one or more first guide holes (for example, blind holes or through holes) for receiving the one or more first guide pins 225 respectively when the socket jig 240 is mounted on the test socket 220. As such, the socket jig 240 can be accurately secured in place on the test socket 220 without undesired lateral movement. In some embodiments, the first guide pins 225 are arranged near a periphery of the test socket 220. In the example of FIG. 2C, only one guide pin 225 is illustrated, but the present application is not limited thereto. In other examples, the number of the guide pins 225 may be two or more to fix the socket jig 240 in place in a more balanced manner. Then, one or more first fasteners 243 may be used for mounting the socket jig 240 onto the test socket 220. For example, the one or more first fasteners 243 may include bolts or screws. In the example shown in FIG. 2C, the number of the first fasteners 243 may be two, which are arranged diagonally with respect to the socket jig 240, thus securing the socket jig 240 in place. It can be appreciated that the number of the first fasteners 243 may be one, three, four or even more in other examples.

Continuing referring to FIG. 2C, the socket jig 240 may also include one or more second guide pins 245 protruding from its upper surface. For example, the socket jig 240 may include one or more blind holes on its upper surface, and the second guide pins 245 are disposed in the blind holes. Accordingly, the probe base 252 includes one or more second guide holes 255 for receiving the one or more second guide pins 245 respectively when the probe base 252 is mounted on the socket jig 240. As such, the probe base 252 can be accurately secured in place on the socket jig 240 without undesired lateral movement. Then, one or more second fasteners 257 may be used for mounting the probe base 252 onto the socket jig 240. For example, the one or more second fasteners 257 may include bolts or screws. Further, there may be a pad 246 disposed between the probe base 252 and the socket jig 240 to prevent movement therebetween. In the example shown in FIG. 2C, the number of second guide pins 245 is two and the number of the second fastener 243 is one, but the present application is not limited thereto. In other examples, there may be more or less second guide pins and/or second fasteners.

FIG. 2D is a cross-sectional and exploded view of the apparatus 200 of FIG. 2B, and a blow-up of an area of the guide block 270 is also illustrated. As shown in FIG. 2D, the guide block 270 may be a plate which covers the non-target contact pins 222b, and have at least one through hole 272 for exposing the at least one target contact pin 222a such that a test tool (e.g., the probe tip 254) can be in contact with the at least one target contact pin 222a through the through hole 272.

In some embodiments, as shown in FIG. 2D, the guide block 270 may include a recess 274 on its upper surface. The recess 274 may be right above the target contact pin 222a and connected with the through hole 272. In some examples, the recess 274 may have an inverted trapezoidal section. In other words, a size of the recess 274 decreases gradually from its upper portion to its lower portion, thus forming the inverted trapezoidal shaped recess 274. Thus, when the socket jig 240 is mounted on the test socket 220, the recess 274 can further guide the probe tip 254 into the through hole 272. However, the present is not limited to the above example. In other examples, the recess 274 may have a side surface perpendicular to the upper surface of the guide block 270.

In some embodiments, a size of a top portion of the through hole 272 is larger than that of a bottom portion of the through hole 272. In this way, it is easier for the probe tip 254 to get access to the target contact pin 222a through the through hole 272. In the example shown in FIG. 2D, the top portion of the through hole 272 may have a size larger than the distal end of the probe tip 254, while the bottom portion of the through hole 272 may have a size suitable for receiving the target contact pin 222a. The top portion of the through hole 272 may have an inverted trapezoidal shaped cross-section, which further facilitates the access of the probe tip 254 to the target contact pin 222a.

After the probe tip 254 is electrically coupled with the target contact pin 222a, a testing path is formed. The testing path extends from the first RF connector 212, passes through the metallic wire of the test board 210, the target contact pin 222a, and the probe tip 254 of the probe assembly 230, and finally reaches the second RF connector 256. As both the first RF connector 212 and the second RF connector 256 are coupled with measurement equipment such as a VNA, an electrical characteristic associated with the testing path can be measured.

In the example shown in FIG. 2D, more than one target contact pins 222a are included within the test socket 220, and more than one probe tips 254 are used to test the more than one target contact pins 222a respectively. A measurement of the electrical characteristic may be carried out between one of target contact pins 222a and one of the probe tips 254, respectively. The measurement may be carried out individually for each pair of the target contact pin 222a and the probe tips 254, to generate multiple measurement results for the target contact pins 222a. The measurement results can be used for calibrating a test result of the electronic device which may be obtained in the test mode.

The discussion herein included numerous illustrative figures that showed various portions of an apparatus for testing an electronic device. For illustrative clarity, such figures did not show all aspects of each exemplary apparatus. Any of the example apparatus provided herein may share any or all characteristics with any or all other apparatus provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for testing an electronic device, comprising:
a test board;
a test socket disposed on the test board, wherein the test socket comprises a socket body, and a plurality of contact pins vertically extending through the socket body; and
a probe assembly comprising a socket jig and a test probe operably mounted on the socket jig, wherein, when the socket jig is mounted on the test socket, the socket jig fixes the test probe relative to the test socket and guides the test probe to contact with a target contact pin of the plurality of contact pins.

2. The apparatus of claim 1, wherein the socket body comprises a socket base and a side wall surrounding the socket base and defining a cavity above the socket base.

3. The apparatus of claim 2, further comprising:
a guide block disposed within the cavity of the socket body, wherein the guide block comprises a through hole to expose the target contact pin.

4. The apparatus of claim 3, wherein the through hole of the guide block further guides the test probe to contact with the target contact pin when the socket jig is mounted on the test socket.

5. The apparatus of claim 4, wherein a size of a top portion of the through hole is larger than that of a bottom portion of the through hole.

6. The apparatus of claim 3, further comprising:
an inner plate disposed between the socket body and the guide block, wherein the plurality of contact pins vertically extend through the inner plate.

7. The apparatus of claim 1, wherein the test probe comprises a probe base and a probe tip mounted on the probe base, the probe base is operably mounted on the socket jig, and the probe tip is guided to contact with the target contact pin.

8. The apparatus of claim 7, wherein the socket jig comprises a through hole, and the probe tip passes through the through hole of the socket jig to contact with the target contact pin.

9. The apparatus of claim 7, further comprising:
one or more first fasteners adapted for mounting the socket jig onto the test socket; and
one or more second fasteners adapted for mounting the probe base onto the socket jig.

10. The apparatus of claim 9, wherein the one or more first fasteners and/or the one or more second fasteners comprise bolts.

11. The apparatus of claim 9, wherein the test socket comprises one or more first guide pins protruding from its upper surface, and the socket jig comprises one or more first guide holes for receiving the one or more first guide pins respectively when the socket jig is mounted on the test socket.

12. The apparatus of claim 9, wherein the socket jig comprises one or more second guide pins protruding from its upper surface, and the probe base comprises one or more second guide holes for receiving the one or more second guide pins respectively when the probe base is mounted on the socket jig.

13. The apparatus of claim 1, further comprising:
a test board having a device placement region, wherein the test socket is mounted on the device placement region of the test board and the target contact pin is electrically connected with the test board.

14. The apparatus of claim 1, wherein the plurality of contact pins comprise pogo pins.
